(19) United States
(12) Patent Application Publication
(10) Pub. No.: US 2013/0176056 A1
(43) Pub. Date: Jul. 11, 2013

(54) INVERTER DELAY COMPENSATION CIRCUIT

(71) Applicants: Jong Sam KIM, Icheon-si (KR); Jin Hee Cho, Icheon-si (KR)

(72) Inventors: Jong Sam KIM, Icheon-si (KR); Jin Hee Cho, Icheon-si (KR)

(73) Assignee: Sk HYNIX INC., Icheon-si (KR)

(21) Appl. No.: 13/602,105

(22) Filed: Sep. 1, 2012

(30) Foreign Application Priority Data
Jan. 10, 2012 (KR) 10-2012-0002936

(51) Int. Cl. H03K 3/00

(52) U.S. Cl. 327/2

(57) ABSTRACT

An inverter delay compensation circuit includes a comparison determination unit including a first delay circuit configured for receiving a reference signal and having an inverter chain and a second delay circuit configured for receiving the reference signal and more insensitive to a PVT variation than the first delay circuit, and configured to compare delay amounts of signals obtained by passing the reference signal through the first and second delay circuits, respectively, and the comparison determination unit configured for generating a plurality of control signals; and a compensation circuit unit configured to compensate for a delay amount of an input signal in response to the plurality of control signals and configured to output an output signal.

### CROSS-REFERENCES TO RELATED APPLICATION

The present application claims priority under 35 U.S.C. §119(a) to Korean application number 10-2012-0002936, filed on Jan. 10, 2012, in the Korean Intellectual Property Office, which is incorporated herein by reference in its entirety.

### BACKGROUND

1. Technical Field

The present invention generally relates to a semiconductor integrated circuit, and more particularly, to an inverter delay compensation circuit of a semiconductor integrated circuit.

2. Related Art

In general, a semiconductor integrated circuit uses a ring oscillator to generate an oscillation signal, and the ring oscillator includes an inverter chain having a plurality of inverters.

Therefore, according to the delay characteristics of the inverters, the delay characteristic of the ring oscillator to generate an oscillation signal inside the semiconductor integrated circuit may change. When the propagation speed of signals inside the semiconductor integrated circuit changes according to the delay characteristic, the speed change may have an effect on the entire speed of the semiconductor integrated circuit using the oscillation signal.

Conventionally, a plurality of semiconductor chips are formed over a silicon wafer, and a test pattern capable of measuring an inverter delay characteristic is added to a scribe lane at an interface between the respective semiconductor chips, in order to monitor whether or not the process was normally performed. When the monitoring result does not reach a target value, it is impossible to secure the operation reliability of the semiconductor integrated circuit. In this case, the semiconductor chips may be discarded.

Therefore, the circuit capable of measuring and compensating for inverter delay characteristics in the scribe lane area or the semiconductor chips may be modified to solve the problem of the conventional semiconductor integrated circuit.

### SUMMARY

In an embodiment, an inverter delay compensation circuit includes: a comparison determination unit including a first delay circuit configured for receiving a reference signal and having an inverter chain and a second delay circuit configured for receiving the reference signal and more insensitive to a PVT variation than the first delay circuit, and configured to compare delay amounts of signals obtained by passing the reference signal through the first and second delay circuits, respectively, and the comparison determination unit configured for generating a plurality of control signals; and a compensation circuit unit configured to compensate for a delay amount of an input signal in response to the plurality of control signals and configured to output an output signal.

### BRIEF DESCRIPTION OF THE DRAWINGS

Features, aspects, and embodiments are described in conjunction with the attached drawings, in which:

FIG. 1 is a schematic block diagram of an inverter delay compensation circuit according to an embodiment;

FIG. 2 is a circuit diagram of a comparison determination unit of FIG. 1;

FIG. 3 is a circuit diagram of a compensation circuit unit of FIG. 1; and

FIGS. 4A to 4C are timing diagrams of the inverter delay compensation circuit according to an embodiment.

### DETAILED DESCRIPTION

Hereinafter, an inverter delay compensation circuit according to an embodiment will be described below with reference to the accompanying drawings through various embodiments.

In general, a ring oscillator used in a semiconductor integrated circuit may include an inverter chain. Therefore, when an inverter delay circuit is implemented by modeling an inverter used in the ring oscillator, a delay amount of the ring oscillator may be obtained based on a delay amount of the inverter delay circuit.

The inverters of the semiconductor integrated circuit may generally be implemented with transistors which may be sensitive to process/voltage/temperature variations (hereafter, referred to as PVT variations). Accordingly, the inverter delay circuit including transistors may be sensitive to PVT variations.

For example, when the inverter delay circuit has a normal delay amount at a driving voltage of 1.5V and a normal temperature of 25° C., a delay amount of the inverter delay circuit at a driving voltage of less than 1.5V or a temperature higher than the normal temperature is larger than the normal delay amount. Furthermore, a delay amount of the inverter delay circuit at a driving voltage of more than 1.5V or a temperature lower than the normal temperature is smaller than the normal delay amount.

Therefore, based on the inverter delay circuit having the normal delay amount and a delay circuit having the same delay amount as the inverter delay circuit and relatively insensitive to PVT variations, it is possible to determine a delay amount of the inverter delay circuit caused by PVT variations. Additionally, after substantially the same signals are inputted to the inverter delay circuit and the delay circuit, output signals of the inverter delay circuit and the delay circuit may be compared to determine the delay amount of the inverter delay circuit caused by the PVT variations.

Here, the delay circuit relatively insensitive to the PVT variations may include a resist capacitance (RC) delay circuit.

The RC delay circuit may include a plurality of resistors connected in series between input and output terminals thereof and a plurality of capacitors connected between a ground terminal and nodes formed between the respective resistors. The RC delay circuit receiving a predetermined signal through the input terminal delays the signal through the resistors and the capacitors, and outputs a predetermined signal to the output terminal.

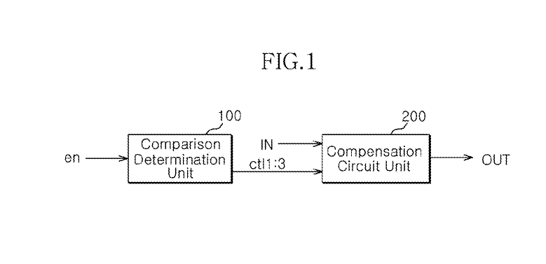

FIG. 1 is a schematic block diagram of an inverter delay compensation circuit according to an embodiment.

Referring to FIG. 1, the inverter delay compensation circuit according to an embodiment may include a comparison determination unit 100 and a compensation circuit unit 200.

The comparison determination unit 100 may be configured to receive a reference signal EN and generate first to third control signals ctl 1:3.

Specifically, when receiving the reference signal EN, the comparison determination unit 100 may compare a delay amount is caused by an inverter delay circuit to a delay amount caused by a delay circuit insensitive to PVT variations, in order to sense a PVT variation of the inverter delay circuit. Based on the PVT variation of the inverter delay circuit, the comparison determination unit 100 may generate the first to third control signals ctl 1:3 for determining a delay amount of an input signal IN.

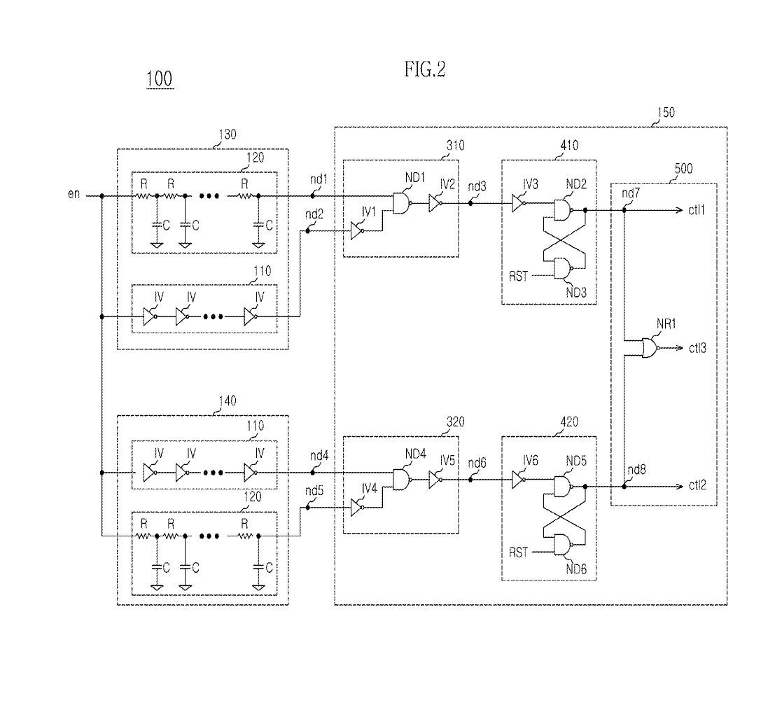

The reference signal EN may be a signal for comparing delay amounts of first and second delay circuits 110 and 120 (see FIG. 2).

The compensation circuit unit 200 may be configured to compensate for the delay amount of the input signal IN in response to the first to third control signals ctl 1:3 and output an output signal OUT.

The input signal IN inputted to the compensation circuit unit 200 may operate in response to an inverter chain used in the semiconductor integrated circuit.

FIG. 2 is a circuit diagram of the comparison determination unit 100 of FIG. 1.

Referring to FIG. 2, the comparison determination unit 100 may include a first delay element 130, a second delay element 140, and a control signal generator 150.

The control signal generator 150 may include a first comparison section 310, a second comparison section 320, a first latch section 410, a second latch section 420, and a control signal output section 500.

The first delay element 130 may include a first delay circuit 110 and a second delay circuit 120. The first delay element 130 may be configured to delay the reference signal EN by a predetermined time and output the delayed reference signal EN to first and second nodes nd1 and nd2.

The first delay circuit 110 of the first delay element 130 may include a plurality of inverters IV. The second delay circuit 120 of the first delay element 130 may include a resist capacitance (RC) delay circuit having a plurality of resistors R and capacitors C.

The plurality of inverters IV included in the first delay circuit 110 of the first delay element 130 may be connected in series, and the first delay circuit 110 may be configured to delay the reference signal EN by a predetermined time and output the delayed reference signal EN to the second node nd2.

The plurality of resistors R included in the second delay circuit 120 of the first delay element 130 may be connected in series between input and output terminals, and the capacitors C may be connected between a ground terminal and nodes between the respective resistors R.

The second delay circuit 120 of the first delay element 130 may be configured to delay the reference signal EN by a predetermined time and output the delayed reference signal EN to the first node nd1.

The second delay element 140 may include a first delay circuit 110 and a second delay circuit 120. The second delay element 140 may be configured to delay the reference signal EN by a predetermined time and output the delayed reference signal EN to fourth and fifth nodes nd4 and nd5.

The first delay circuit 110 of the second delay element 140 may include a plurality of inverters IV. The second delay circuit 120 of the second delay element 140 may include a plurality of resistors R and capacitors C.

The plurality of inverters IV included in the first delay circuit 110 of the second delay element 140 may be connected in series, and the first delay circuit 110 may be configured to delay the reference signal EN by a predetermined time and output the delayed reference signal EN to the fourth node nd4.

The plurality of resistors R included in the second delay circuit 120 of the second delay element 140 may be connected in series between input and output terminals, and the capacitors C may be connected between a ground terminal and nodes between the respective resistors R.

The second delay circuit 120 of the second delay element 140 may be configured to delay the reference signal EN by a predetermined time and output the delayed reference signal EN to the fifth node nd5.

Here, the first and second delay circuits 110 and 120 of the first delay element 130 have the same configuration as the first and second delay circuits 110 and 120 of the second delay element 140.

According to another embodiment, an output signal of the first delay circuit 110 of the first delay element 130 may be is connected to the fourth node nd4 of the second comparison section 320, and an output signal of the second delay circuit 120 of the first delay element 130 may be connected to the fifth node nd5 of the second comparison section 320 (not shown). In this case, it is possible to compare the delay amounts of the reference signals EN using only the first delay element 130.

The control signal generator 150 may be configured to compare the reference signal delay amounts of the first and second delay circuits 110 and 120 and generate the first to third control signals ctl 1:3.

Additionally, the first comparison section 310 may include a first inverter IV1, a first NAND gate ND1, and a second inverter IV2. The first inverter IV1 may be configured to invert an output of the second node nd2. The first NAND gate ND1 may be configured to perform a logic operation on an output signal of the first node nd1 and an output signal of the first inverter IV1. The second inverter IV2 may be configured to invert an output signal of the first NAND gate ND1 and output the inverted signal to the third node nd3.

The second comparison section 320 may include a fourth inverter IV4, a fourth NAND gate ND4, and a fifth inverter IV5. The fourth inverter IV4 may be configured to invert an output of the fifth node nd5. The fourth NAND gate ND4 may be configured to perform a logic operation on an output signal of the fourth node nd4 and an output signal of the fourth inverter IV4. The fifth inverter IV5 may be configured to invert an output signal of the fourth NAND gate ND4 and output the inverted signal to the sixth node nd6.

Referring to FIG. 2, the operation of the first comparison section 310 will be described as follows.

The first comparison section 310 may receive an output signal of the first delay circuit 110 and an output signal of the second delay circuit 120, and may output a predetermined signal to the third node nd3.

Additionally, when the delay amount of the reference signal EN in the first delay circuit 110 of the first delay element 130 increases due to a PVT variation, the first comparison section 310 may generate a signal activated during a predetermined period. That is, when the delay amount of the reference signal EN in the first delay circuit 110 of the first delay element 130 increases due to PVT variations, the first comparison section 310 may output a signal having a predetermined logic level during a predetermined period to the third node nd3.

However, when the delay amount of the reference signal EN in the first delay circuit 110 is small or normal, the first comparison section 310 may generate a deactivated signal.

Referring to FIG. 2, the operation of the second comparison unit 320 will be described as follows.

The second comparison section 320 may receive an output signal of the first delay circuit 110 and an output signal of the second delay circuit 120 and may output a predetermined signal to the sixth node nd6.

Additionally, when the delay amount of the reference signal EN in the first delay circuit 110 of the second delay element 140 decreases due to a PVT variation, the second comparison section 320 may generate a signal activated during a predetermined period. That is, when the delay amount of the reference signal EN in the first delay circuit 110 of the second delay element 140 decreases due to a PVT variation, the second comparison section 320 may output a signal having a predetermined logic level during a predetermined period to the sixth node nd6.

However, when the delay amount of the reference signal EN in the first delay element 110 is large or normal, the second comparison section 320 may generate a deactivated signal.

The first latch section 410 may include a third inverter IV3, a second NAND gate ND2, and a third NAND gate ND3. The third inverter IV3 may be configured to invert an output signal of the third node nd3. The second NAND gate ND2 may be configured to perform a logic operation on an output signal of the third inverter IV3 and an output signal of the third NAND gate ND3 and output the operation result to a seventh node nd7. The third NAND gate ND3 may be configured to perform a logic operation on an output signal of the seventh node nd7 and a reset signal RST and output the operation result.

The second latch section 420 may include a sixth inverter IV6, a fifth NAND gate ND5, and a sixth NAND gate ND6. The sixth inverter IV6 may be configured to invert an output signal of the sixth node nd6. The fifth NAND gate ND5 may be configured to perform a logic operation on an output signal of the sixth inverter IV6 and an output signal of the sixth NAND gate ND6 and output the operation result to an eighth node nd8. The sixth NAND gate ND6 may be configured to perform a logic operation on an output signal of the eighth node nd8 and a reset signal RST and output the operation result.

The reset signal RST may be a mode register set (MRS) signal to decide whether or not to reset the first and second latch sections 410 and 420.

Referring to FIG. 2, the operations of the first and second latch sections 410 and 420 will be described as follows.

First, when the delay amount of the reference signal EN in the first delay circuit 110 increases due to a PVT variation, the first comparison section 310 may output a signal activated during a predetermined period to the third node nd3. The first latch section 410 receives the output signal of the third node nd3 and may output the activated signal to the seventh node nd7.

Then, the second comparison section 320 may generate a deactivated signal, and the second latch section 420 receiving the deactivated signal may output the deactivated signal to the eighth node nd8.

Next, when the delay amount of the reference signal EN in the first delay circuit 110 decreases due to a PVT variation, the first comparison section 310 may generate a deactivated signal, and the first latch section 410 receiving the deactivated signal may output the deactivated signal to the seventh node nd7.

Then, the second comparison section 320 may output a signal activated during a predetermined period to the sixth node nd6. The second latch section 420 receives the output signal of the sixth node nd6, and may output the activated signal to the eighth node nd8.

The control signal output section 500 may include the seventh node nd7, the eight node nd8, and a first NOR gate NR1. The seventh node nd7 may be configured to output a first control signal ctl1. The eighth node nd8 may be configured to output a second control signal ctl2. The first NOR gate NR1 may be configured to perform a logic operation on the output signal of the seventh node nd7 and the output signal of the eighth node nd8 and may output a third control signal ctl3.

Referring to FIG. 2, the operation of the control signal output section 500 will be described as follows.

First, when the delay amount of the reference signal EN in the first delay circuit 110 increases due to a PVT variation, the control signal output section 500 may output an activated signal as the first control signal ctl1, and may output a deactivated signal as the second control signal ctl2. Additionally, the first NOR gate NR1 of the control signal output section 500 performs a logic operation on the first and second control signals ctl1 and ctl2, and may output a deactivated signal as the third control signal ctl3.

Next, when the delay amount of the reference signal EN in the first delay circuit 110 decreases due to a PVT variation, the control signal output section 500 may output a deactivated signal as the first control signal ctl1, and may output an activated signal as the second control signal ctl2. Additionally, the first NOR gate NR1 of the control signal output section 500 performs a logic operation on the first and second control signals ctl1 and ctl2, and may output a deactivated signal as the third control signal ctl3.

When the delay amount of the reference signal EN in the first delay circuit 110 is normal, the control signal output section 500 may output deactivated signals as the first and second control signals ctl1 and ctl2. Then, the first NOR gate NR1 of the control signal output section 500 may perform a logic operation on the first and second control signals ctl1 and ctl2 and may output an activated signal as the third control signal ctl3.

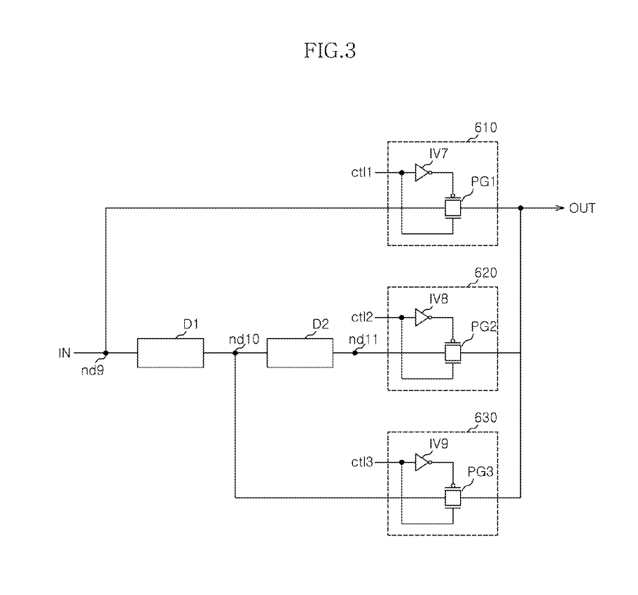

FIG. 3 is a circuit diagram of the compensation circuit unit 200 of FIG. 1.

The compensation circuit unit 200 may include a first delay element D1, a second delay element D2, and first to third switches 610 to 630.

The first delay element D1 may be configured to delay an output signal of a ninth node nd9 by a predetermined time and output the delayed signal to a tenth node nd10.

The second delay element D2 may be configured to delay an output signal of the tenth node nd10 by a predetermined time and output the delayed signal to an eleventh node nd11.

The ninth node nd9 may receive an input signal IN.

The first switch 610 may include a seventh inverter IV7 and a first pass gate PG1. The seventh inverter IV7 may be configured to invert the first control signal ctl1. The first pass gate PG1 may be configured to decide whether or not to output the output signal of the ninth node nd9 in response to an output signal of the seventh inverter IV7 and the first control signal ctl1.

The second switch 620 may include an eighth inverter IV8 and a second pass gate PG2. The eighth inverter IV8 may be configured to invert the second control signal ctl2. The second pass gate PG2 may be configured to decide whether or not to output an output signal of the eleventh node nd11 in response to an output signal of the eighth inverter IV8 and the second control signal ctl2.

The third switch 630 may include a ninth inverter IV9 and a third pass gate PG3. The ninth inverter IV9 may be configured to invert the third control signal ctl3. The third pass gate PG3 may be configured to decide whether or not to output an output signal of the tenth node nd10 in response to an output signal of the ninth inverter IV9 and the third control signal ctl3.

Referring to FIG. 3, the operation of the compensation circuit unit 200 will be described as follows.

The compensation circuit unit 200 may compensate a delay amount of the input signal IN and may output an output signal OUT.

First, when the delay amount of the reference signal EN in the first delay circuit 110 increases, the first control signal ctl1 is activated, and the second and third control signals ctl2 and ctl3 are deactivated.

Then, the first pass gate PG1 may output the signal of the ninth node nd9.

When the delay amount of the reference signal EN in the first delay circuit 110 decreases, the second control signal ctl2 is activated, and the first and third control signals ctl1 and ctl3 are deactivated.

Then, the second pass gate PG2 may output the signal of the eleventh node nd11.

When the delay amount of the reference signal EN in the first delay circuit 110 is normal, the third control signal ctl3 is activated, and the first and second control signals ctl1 and ctl2 are deactivated.

In other words, when the delay amount of the reference signal EN in the first delay circuit 110 increases, the input signal IN may be outputted as the output signal OUT without delay. Furthermore, when the delay amount of the reference signal EN in the first delay circuit 110 decreases, the input signal IN may be delayed by the first and second delay elements D1 and D2 and outputted as the output signal OUT. Furthermore, when the delay amount of the reference signal EN in the first delay circuit 110 is normal, the input signal IN may be delayed by the first delay element D1 and outputted as the output signal OUT.

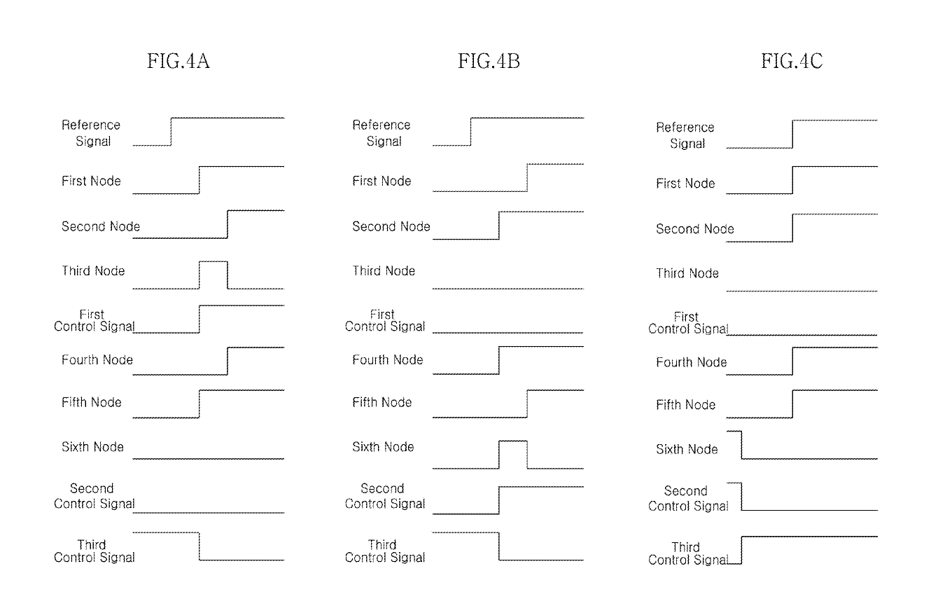

FIG. 4A is a timing diagram of the inverter delay compensation circuit according to an embodiment, when the delay amount of the reference signal EN in the first delay circuit 110 is larger than the delay amount of the reference signal EN in the second delay circuit 120.

Specifically, FIG. 4A is a timing diagram of the comparison determination unit 100, when the delay amount of the reference signal EN in the first delay circuit 110 is larger than the delay amount of the reference signal EN in the second delay circuit 120.

Referring to FIGS. 2, 3, and 4A, the operation of the inverter delay compensation circuit according to an embodiment may be described as follows.

The reference signal EN is a signal for comparing the delay amounts of the first and second delay circuits 110 and 120, and transitions from a low level to a high level (i.e., voltage level, or voltage logic level).

Then, when the delay amount of the reference signal EN in the first delay circuit 110 becomes larger than the delay amount of the reference signal EN in the second delay circuit 120 due to a PVT variation, the output signal of the second node nd2 transitions to a high level after the output signal of the first node nd1, and the output signal of the fourth node nd4 transitions to a high level after the output signal of the fifth node nd5.

The first comparison unit 310 may compare the output signals of the first and second nd1 and nd2, and may output a high-level signal to the third node nd3 from a time point when the output signal of the first node nd1 transitions to a high level to a time point when the output signal of the second node nd2 transitions to a high level.

In other words, when the delay amount of the reference signal EN in the first delay circuit 100 becomes larger than the delay amount of the reference signal EN in the second delay circuit 120 due to a PVT variation, the output signal of the third node nd3 transitions to a high level from a time point when the second delay circuit 120 delays the reference signal EN by a predetermined time and may output the delayed reference signal EN to the first node nd1, and transitions to a low level at a time point when the first delay circuit 110 delays the reference signal EN by a predetermined time and may output the delayed reference signal EN to the second node nd2.

The first latch section 410 latches the output signal of the third node nd3. When the output signal of the third node nd3 is maintained at a high level during a predetermined time, the first control signal ctl1 outputted from the first latch section 410 transitions to a high level from a time point when the output signal of the third node nd3 becomes a high level.

The second comparison section 320 may compare the output signals of the fourth and fifth nodes nd4 and nd5, and may output a low-level output signal to the sixth node nd6.

The second latch section 420 latches the output signal of the sixth node nd6. When the output signal of the sixth node nd6 is becomes a low level, the second control signal ctl2 outputted from the latch unit 420 becomes a low level.

The control signal output section 500 performs a logic operation on the first and second control signals ctl1 and ctl2 and may output the low-level third control signal ctl3.

The compensation circuit unit 200 receiving the input signal IN may output the output signal OUT in response to the first to third control signals ctl 1:3.

The first switch 610 receiving the input signal IN may output the output signal OUT in response to the high-level first control signal ctl1.

The second switch 620 may block the output signal of the eleventh node nd11 in response to the low-level second control signal ctl2.

The third switch 630 may block the output signal of the tenth node nd10 in response to the low-level third control signal ctl3.

That is, when the delay amount of the reference signal EN in the first delay circuit 110 becomes larger than in the second delay circuit 120 due to a PVT variation, the compensation circuit unit 200 may output the input signal IN without delay.

FIG. 4B is a timing diagram of the inverter delay compensation circuit according to an embodiment, when the delay amount of the reference signal EN in the first delay circuit 110 is smaller than the delay amount of the reference signal EN in the second delay circuit 120.

Specifically, FIG. 4B is a timing diagram of the comparison determination unit 100, when the delay amount of the reference signal EN in the first delay circuit 110 is smaller than the delay amount of the reference signal EN in the second delay circuit 120.

Referring to FIGS. 2, 3, and 4B, the operation of the inverter delay compensation circuit according to an embodiment may be described as follows.

The reference signal EN is a signal for comparing the delay amounts of the first and second delay circuits 110 and 120, and transitions from a low level to a high level (i.e., voltage level, or voltage logic level).

Then, when the delay amount of the reference signal EN in the first delay circuit 110 becomes smaller than the delay amount of the reference signal EN in the second delay circuit 120 due to a PVT variation, the output signal of the second node nd2 transitions to a high level before the output signal of the first node nd1, and the output signal of the first node nd4 transitions to a high level before the output signal of the fifth node nd5.

The second comparison unit 320 may compare the output signals of the fourth and fifth nodes nd4 and nd5, and may output a high-level signal to the sixth node nd6 from a time point when the output signal of the fourth node nd4 transitions to a high level to a time point when the output signal of the fifth node nd5 transitions to a high level.

In other words, when the delay amount of the reference signal EN in the first delay circuit 110 becomes smaller than the delay amount of the reference signal EN in the second delay circuit 120 due to a PVT variation, the output signal of the sixth node nd6 transitions to a high level from a time point when the first delay circuit 110 delays the reference signal EN by a predetermined time and may output the delayed reference signal EN to the fourth node nd4, and transitions to a low level at a time point when the second delay circuit 120 delays the reference signal EN by a predetermined time and may output the delayed reference signal EN to the fifth node nd5.

The second latch section 420 latches the output signal of the sixth node nd6. When the output signal of the sixth node nd6 is maintained at a high level during a predetermined time, the second control signal ctl2 outputted from the second latch unit 420 transitions to a high level from a time point when the output signal of the sixth node nd6 becomes a high level.

The first comparison section 310 may compare the output signals of the first and second node nd1 and nd2, and may output a low-level output signal to the third node nd3.

The first latch section 410 latches the output signal of the third node nd3. When the output signal of the third node nd3 becomes a low level, the first control signal ctl1 outputted from the first latch section 410 becomes a low level.

The control signal output section 500 may perform a logic operation on the first and second control signals ctl1 and ctl2, and may output the low-level third control signal ctl3.

The compensation circuit unit 200 receiving the input signal IN may output the output signal OUT in response to the first to third control signals ctl 1:3.

The first switch 610 may block the output signal of the ninth node nd9 in response to the low-level first control signal ctl1.

The second switch 620 may block the output signal of the eleventh node nd11 in response to the high-level second control signal ctl2.

The third switch 630 may block the output signal of the tenth node nd10 in response to the low-level third control signal ctl3.

That is, when the delay amount of the reference signal EN in the first delay circuit 110 becomes smaller than in the second delay circuit 120 due to a PVT variation, the compensation circuit unit 200 delays the input signal IN through the first and second delay elements D1 and D2, and may output the output signal OUT.

FIG. 4C is a timing diagram of the inverter delay compensation circuit according to an embodiment, when the delay amount of the reference signal EN in the first delay circuit 110 is equal to the delay amount of the reference signal EN in the second circuit 120.

Specifically, FIG. 4C is a timing diagram of the comparison determination unit 100, when the delay amount of the reference signal EN in the first delay circuit 110 is equal to the delay amount of the reference signal EN in the second delay circuit 120.

Referring to FIGS. 2, 3, and 4C, the operation of the inverter delay compensation circuit according to an embodiment may be described as follows.

The reference signal EN is a signal for comparing the delay amounts of the first and second delay circuits 110 and 120, and transitions from a low level to a high level (i.e., voltage level, or voltage logic level).

When the delay amount of the reference signal EN in the first delay circuit 110 is equal to the delay amount of the reference signal EN in the second delay circuit 120 without a PVT variation, the output signals of the first node nd1, the second node nd2, the fourth node nd4, and the fifth node nd5 transit to a high level at the same time.

Then, the first comparison section 310 performs a logic operation on the output signals of the first and second nodes nd1 and nd2, and may output a low-level output signal to the third node nd3. The second comparison section 320 performs a logic operation on the output signals of the fourth and fifth nodes nd4 and nd5, and may output a low-level output signal to the sixth node nd6.

The first latch section 410 latches the output signal of the third node nd3. When the output signal of the third node nd3 becomes a low level, the first control signal ctl1 outputted from the first latch section 410 becomes a low level.

The second latch section 410 latches the output signal of the sixth node nd6. When the output signal of the sixth node nd6 becomes a low level, the second control signal ctl2 outputted from is the second latch section 420 becomes a low level.

The control signal output section 500 performs a logic operation on the first and second control signals ctl1 and ctl2, and may output the high-level third control signal ctl3.

The compensation circuit unit 200 receiving the input signal IN may output the output signal OUT in response to the first to third control signals ctl 1:3.

The first switch 610 may block the output signal of the ninth node nd9 in response to the low-level first control signal ctl1.

The second switch 620 may block the output signal of the eleventh node nd11 in response to the low-level second control signal ctl2.

The third switch 630 may output the output signal of the tenth node nd10 in response to the high-level third control signal ctl3.

That is, when the delay amount of the reference signal EN in the second delay circuit 120 is equal to the delay amount of the reference signal EN in the first delay circuit 110, the compensation circuit unit 200 delays the input signal IN through the first delay element D1, and may output the output signal OUT.

While various embodiments have been described above, it will be understood to those skilled in the art that the embodiments described are by way of example only. Accordingly, the inverter delay compensation circuit described herein should not be limited based on the described embodiments.

What is claimed is:

1. An inverter delay compensation circuit comprising:
a comparison determination unit comprising a first delay circuit configured for receiving a reference signal and having an inverter chain and a second delay circuit configured for receiving the reference signal and more insensitive to a PVT variation than the first delay circuit, and configured to compare delay amounts of signals obtained by passing the reference signal through the first and second delay circuits, respectively, and the comparison determination unit configured for generating a plurality of control signals; and
a compensation circuit unit configured to compensate for a delay amount of an input signal in response to the plurality of control signals and configured to output an output signal.

2. The inverter delay compensation circuit according to claim 1, wherein the second delay circuit comprises a resist capacitance (RC) delay circuit having a plurality of resistors and capacitors.

3. The inverter delay compensation circuit according to claim 1, wherein the plurality of control signals comprise first to third control signals, and
when a delay amount of the reference signal in the first delay circuit is larger than the delay amount of the reference signal in the second delay circuit due to a PVT variation, the comparison determination unit outputs an activated first control signal, a deactivated second control signal, and a deactivated third control signal.

4. The inverter delay compensation circuit according to claim 1, wherein the plurality of control signals comprise first to third control signals, and
when a delay amount of the reference signal in the first delay circuit is smaller than the delay amount of the reference signal in the second delay circuit due to a PVT variation, the comparison determination unit outputs an activated second control signal, a deactivated first control signal, and a deactivated third control signal.

5. The inverter delay compensation circuit according to claim 1, wherein the plurality of control signals comprise first to third control signals, and
when a delay amount of the reference signal in the first delay circuit is equal to the delay amount of the reference signal in the second delay circuit, the comparison determination unit outputs an activated third control signal, a deactivated first control signal, and a deactivated second control signal.

6. The inverter delay compensation circuit according to claim 1, wherein the comparison determination unit further comprises a control signal generator configured to receive output signals of the first and second delay circuits and output the control signals.

7. The inverter delay compensation circuit according to claim 6, wherein the control signal generator comprises:
a first comparison section configured to receive the output signals of the first and second delay circuits, compare delay amounts of the reference signals, and output a comparison result to a first node;
a second comparison section configured to receive the output signals of the first and second delay circuits, compare delay amounts of the reference signals, and output a comparison result to a second node;
a first latch section configured to output a first control signal in response to an output signal of the first node and a reset signal;
is a second latch section configured to output a second control signal in response to an output signal of the second node and a reset signal; and
a control signal output section configured to output the first control signal, the second control signal, and a third control signal obtained by performing a logic operation on the first and second control signals.

8. The inverter delay compensation circuit according to claim 7, wherein the first comparison section outputs a signal activated during a predetermined time to the first node when the delay amount of the reference signal in the first delay circuit is larger than the delay amount of the reference signal in the second delay circuit due to a PVT variation, outputs a deactivated signal to the first node when the delay amount of the reference signal in the first delay circuit is smaller than the delay amount of the reference signal in the second delay circuit due to a PVT variation, and outputs a deactivated signal to the first node when the delay amount of the reference signal in the first delay circuit is equal to the delay amount of the reference signal in the second delay circuit.

9. The inverter delay compensation circuit according to claim 7, wherein the second comparison section outputs a deactivated signal to the first node when the delay amount of the reference signal in the first delay circuit is larger than the delay amount of the is reference signal in the second delay circuit due to a PVT variation, outputs a signal activated during a predetermined time to the first node when the delay amount of the reference signal in the first delay circuit is smaller than the delay amount of the reference signal in the second delay circuit due to a PVT variation, and outputs a deactivated signal to the first node when the delay amount of the reference signal in the first delay circuit is equal to the delay amount of the reference signal in the second delay circuit.

10. The inverter delay compensation circuit according to claim 7, wherein the first comparison section comprises:
a first inverter configured to invert the output signal of the first delay circuit;
a first NAND gate configured to perform a logic operation on an output signal of the first inverter and the output signal of the second delay circuit; and
a second inverter configured to invert an output signal of the first NAND gate.

11. The inverter delay compensation circuit according to claim 7, wherein the second comparison section comprises:
a third inverter configured to invert the output signal of the second delay circuit;
a second NAND gate configured to perform a logic operation on an output signal of the third inverter and the output signal of the first delay circuit; and
a fourth inverter configured to invert an output signal of the second NAND gate.

12. The inverter delay compensation circuit according to claim 7, wherein the control signal output section comprises a NOR gate configured to perform a logic operation on the first and second control signals.

13. The inverter delay compensation circuit according to claim 7, wherein the reset signal comprises a mode register set (MRS) signal.

14. The inverter delay compensation circuit according to claim 1, wherein the compensation circuit unit comprises:
a first delay element configured to receive the input signal and delay the received signal by a predetermined time;
a second delay element configured to receive an output signal of the first delay element and delay the received signal by a predetermined time; and
a plurality of switches configured to receive the input signal, the output signal of the first delay element, and an output signal of the second delay element, and decide whether or not to output the output signal in response to the plurality of control signals.

15. The inverter delay compensation circuit according to claim 14, wherein the plurality of switches comprise:
a first switch configured to receive the input signal and decide whether or not to output the output signal in response to the first control signal;
a second switch configured to receive the output signal of the second delay element and decide whether or not to output the output signal in response to the second control signal; and
a third switch configured to receive the output signal of the first delay element and decide whether or not to output the output signal in response to the third control signal.
